(19) United States
(12) Patent Application Publication
(10) Pub. No.: US 2025/0318364 A1
(43) Pub. Date: Oct. 9, 2025

(54) DISPLAY DEVICE INCLUDING SENSOR HOLE IN PIXEL DEFINING LAYER AND ELECTRONIC DEVICE INCLUDING THE SAME

(71) Applicant: SAMSUNG DISPLAY CO., LTD., YONGIN-SI (KR)

(72) Inventor: HYUN-SEOK JEONG, Yongin-si (KR)

(21) Appl. No.: 19/013,699

(22) Filed: Jan. 8, 2025

(30) Foreign Application Priority Data
Apr. 8, 2024 (KR) 10-2024-0047167

(51) Int. Cl. H10K 59/122

(52) U.S. Cl. CPC H10K 59/122

(57) ABSTRACT

A display device includes pixel electrodes disposed on a substrate, and a pixel defining layer including pixel openings and a sensor hole. The pixel openings expose a portion of the corresponding pixel electrodes. The sensor hole is disposed with one pixel opening on one side thereof and two pixel openings on another side thereof. The first pixel opening includes a first side adjacent to the sensor hole, and a profile of the first side curves around the sensor hole in a plan view. The first pixel opening has a concave shape with respect to a direction away from the sensor hole along the profile of the first side in the plan view.

### CROSS-REFERENCE TO RELATED APPLICATION(S)

This application claims priority 35 U.S.C. § 119 to Korean Patent Application No. 10-2024-0047167, filed in the Korean Intellectual Property Office on Apr. 8, 2024, which is hereby incorporated by reference in its entirety.

### TECHNICAL FIELD

The present disclosure relates to a display device and an electronic device that includes the display device and, more particularly, to a display device that includes a sensor hole in a pixel defining layer and an electronic device that includes the display device.

### DISCUSSION OF THE RELATED ART

The importance of display devices has been increasing in modern times. Display devices are an effective means of providing visual information to a user and more recently, some display devices are used in conjunction with various sensors.

### SUMMARY

A display device includes first to third pixel electrodes disposed on a substrate, and a pixel defining layer including a first pixel opening, a second pixel opening, a third pixel opening, and a sensor hole. The first pixel opening exposes a portion of the first pixel electrode, the second pixel opening exposes a portion of the second pixel electrode, the third pixel opening exposes a portion of the third pixel electrode, and the sensor hole is disposed with one pixel opening of the first to third pixel openings on one side thereof and two remaining pixel openings of the first to third pixel openings on another side thereof. The first pixel opening has a first side adjacent to the sensor hole, and a profile of the first side curves around the sensor hole in a plan view. The first pixel opening has a concave shape with respect to a direction away from the sensor hole along the profile of the first side in the plan view.

The first pixel opening may further include a second side that is opposite to the first side, and a profile of the second side may be the same as the profile of the first side in the plan view.

The first pixel opening may have a convex shape with respect to the direction away from the sensor hole along the profile of the second side in the plan view.

A planar region defined along sides of the second pixel opening and sides of the third pixel opening may have a third side adjacent to the sensor hole, and a profile of the third side may curve around the sensor hole in the plan view. The planar region may have a concave shape with respect to the direction away from the sensor hole along the profile of the third side in the plan view.

In the plan view, the first side of the first pixel opening and the third side of the planar region may face each other in a first direction with the sensor hole interposed therebetween.

The second pixel opening may be disposed in the first direction from the first pixel opening. The third pixel opening may be disposed in the first direction from the first pixel opening. The second pixel opening and the third pixel opening may be disposed along a second direction that is perpendicular to the first direction.

The planar region may further include a fourth side that is opposite to the third side, and a profile of the fourth side may be mirror symmetrical to the profile of the third side in the plan view.

The planar region may further have a fourth side that is opposite to the third side, and a profile of the fourth side may be the same as the profile of the third side in the plan view.

The first pixel opening, the second pixel opening, the third pixel opening, and the sensor hole may be spaced apart from each other in the plan view.

The pixel defining layer may include a light blocking material.

The display device may further include an optical device disposed under the substrate to correspond to the sensor hole.

The display device may further include a plurality of unit light emitting areas repeatedly arranged on the substrate. Each of the plurality of unit light emitting areas may include a first light emitting area corresponding to the first pixel opening, a second light emitting area corresponding to the second pixel opening, and a third light emitting area corresponding to the third pixel opening. Light emitted from the first light emitting area may have a first color, light emitted from the second light emitting area may have a second color that is different from the first color, and light emitted from the third light emitting area may have a third color that is different from the first color and the second color.

A display device includes first to third pixel electrodes disposed on a substrate, and a pixel defining layer including a first pixel opening, a second pixel opening, a third pixel opening, and a sensor hole. The first pixel opening exposes a portion of the first pixel electrode, the second pixel opening exposes a portion of the second pixel electrode, the third pixel opening exposes a portion of the third pixel electrode, and the sensor hole is disposed with one pixel opening of the first to third pixel openings on one side thereof and two remaining pixel openings of the first to third pixel openings on another side thereof. The first pixel opening includes a first sub-pixel opening exposing a first portion of the first pixel electrode and a second sub-pixel opening exposing a second portion of the first pixel electrode. A first planar region is defined along sides of the first sub-pixel opening and sides of the second sub-pixel opening have a first side adjacent to the sensor hole, and a profile of the first side curves around the sensor hole in a plan view. The first planar region has a concave shape with respect to a direction away from the sensor hole along the profile of the first side in the plan view.

The first planar region may further have a second side that is opposite to the first side, and a profile of the second side may be the same as the profile of the first side in the plan view.

The first planar region may have a convex shape with respect to the direction away from the sensor hole along the profile of the second side in the plan view.

A second planar region defined along sides of the second pixel opening and sides of the third pixel opening may have a third side adjacent to the sensor hole, and a profile of the third side may curve around the sensor hole in the plan view. The second planar region may have a concave shape with respect to the direction away from the sensor hole along the profile of the third side in the plan view.

In the plan view, the first side of the first planar region and the third side of the second planar region may face each other in a first direction with the sensor hole interposed therebetween.

The second pixel opening may be disposed in the first direction from the first pixel opening. The third pixel opening may be disposed in the first direction from the first pixel opening. The second pixel opening and the third pixel opening may be disposed along a second direction that is perpendicular to the first direction. The first sub-pixel opening and the second sub-pixel opening may be disposed along the second direction.

The second planar region further may have a fourth side that is opposite to the third side, and a profile of the fourth side may be mirror symmetrical to or may be the same as the profile of the third side in the plan view.

The first pixel opening, the second pixel opening, the third pixel opening, and the sensor hole may be spaced apart from each other in the plan view.

The pixel defining layer may include a light blocking material.

The display device may further include an optical device disposed under the substrate to correspond to the sensor hole.

The display device may further include a plurality of unit light emitting areas repeatedly arranged on the substrate. Each of the plurality of unit light emitting areas may include a first light emitting area corresponding to the first pixel opening, a second light emitting area corresponding to the second pixel opening, and a third light emitting area corresponding to the third pixel opening. Light emitted from the first light emitting area may have a first color, light emitted from the second light emitting area may have a second color that is different from the first color, and light emitted from the third light emitting area may have a third color that is different from the first color and the second color.

An electronic device includes a display device and a power supply configured to provide power to the display device. The display device includes first to third pixel electrodes disposed on a substrate, and a pixel defining layer including a first pixel opening, a second pixel opening, a third pixel opening, and a sensor hole. The first pixel opening exposes a portion of the first pixel electrode, the second pixel opening exposes a portion of the second pixel electrode, the third pixel opening exposes a portion of the third pixel electrode, and the sensor hole is disposed with one pixel opening of the first to third pixel openings on one side thereof and two remaining pixel openings of the first to third pixel openings on another side thereof. The first pixel opening has a first side adjacent to the sensor hole, and a profile of the first side curves around the sensor hole in a plan view. The first pixel opening has a concave shape with respect to a direction away from the sensor hole along the profile of the first side in the plan view.

The pixel defining layer may define the first to third pixel openings defining the light emitting areas and the sensor hole disposed with one pixel opening of the first to third pixel openings on one side thereof and two remaining pixel openings of the first to third pixel openings on another side thereof. A long side of the first pixel opening and one side of each of the second and third pixel openings may face each other. For example, an arrangement structure of the first to third pixel openings may be an S-stripe structure. Therefore, a visibility of the display device may be increased.

In addition, in a plan view, each of the first to third pixel openings may have a shape in which a space for forming the sensor hole is sufficiently secured with one pixel opening of the first to third pixel openings on one side thereof and two remaining pixel openings of the first to third pixel openings on another side thereof. For example, according embodiments, even when the arrangement structure of the first to third pixel openings is an S-stripe structure, the sensor hole of the pixel defining layer required for utilizing an optical device may be more easily formed. Therefore, the display device may be more easily designed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a plan view illustrating a display device according to an embodiment.

FIG. 2 is a plan view illustrating an example of a second display area of FIG. 1.

FIG. 3 is a cross-sectional view illustrating the second display area of FIG. 2.

FIG. 4 is a plan view illustrating an example of a first display area of FIG. 1.

FIG. 5 and FIG. 6 are plan views illustrating an examples of the second display area of FIG. 1.

FIG. 7 is a plan view illustrating an example of the second display area of FIG. 1.

FIG. 8 is a plan view illustrating an example of the second display area of FIG. 1.

FIG. 9 is a cross-sectional view illustrating the second display area of FIG. 8.

FIG. 10 is a plan view illustrating an example of the second display area of FIG. 1.

FIG. 11 is a block diagram illustrating an electronic device according to an embodiment.

### DETAILED DESCRIPTION

The invention now will be described more fully hereinafter with reference to the accompanying drawings, in which various embodiments are shown. This invention may, however, be embodied in many different forms, and should not necessarily be construed as limited to the embodiments set forth herein. Rather, these embodiments are provided so that this disclosure will be thorough and complete, and will fully convey the scope of the invention to those skilled in the art. Like reference numerals may refer to like elements throughout the specification and the drawings.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not necessarily be limited by these terms. These terms are used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not necessarily intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, a reference number may indicate a singular element or a plurality of the element. For example, a reference number labeling a singular form of an element within the drawing figures may be used to reference a plurality of the singular element within the text of specification.

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

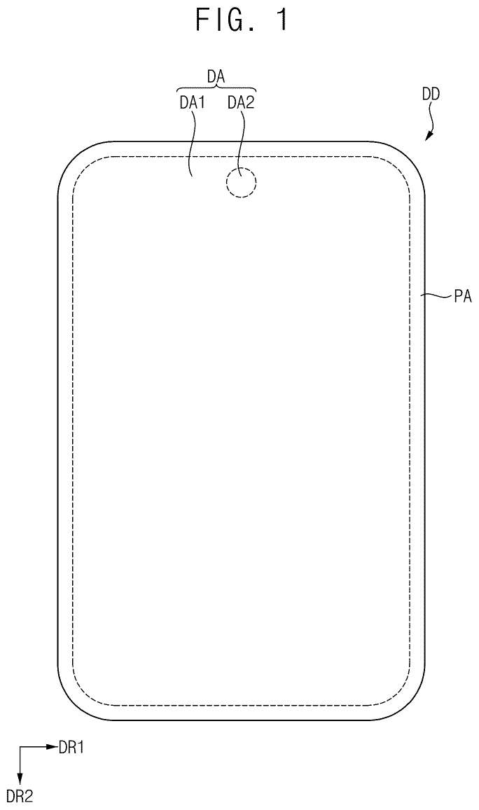

FIG. 1 is a plan view illustrating a display device according to an embodiment.

Referring to FIG. 1, a display device DD may include a display area DA and a peripheral area PA.

The display area DA may be an area that displays an image by generating light or controlling a transmittance of light provided from an external light source. The peripheral area PA may be disposed around the display area DA. For example, the peripheral area PA may surround at least a portion of the display area DA. The peripheral area PA may be an area that does not display an image. However, embodiments are not necessarily limited thereto, and an image may be displayed in at least a portion of the peripheral area PA.

In an embodiment, the display area DA may include a first display area DA1 and a second display area DA2. The first display area DA1 may surround the second display area DA2. However, embodiments are not necessarily limited thereto, and the second display area DA2 may also abut the peripheral area PA. For example, the first display area DA1 may partially surround the second display area DA2.

Light emitting elements may be disposed in each of the first display area DA1 and the second display area DA2. The light emitting elements may emit light, and the image may be generated by combining the light emitted from the light emitting elements.

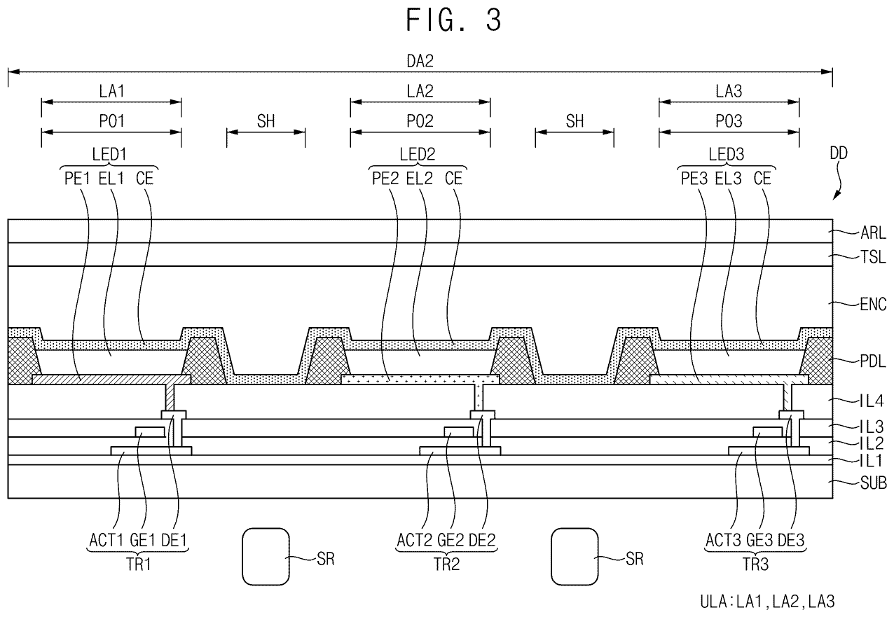

An optical device (e.g., an optical device SR of FIG. 3) may be disposed in the second display area DA2. The optical device might not overlap the light emitting elements disposed in the second display area DA2. The optical device may emit or receive light. In an embodiment, the optical device may be an optical sensor that detects light incident on the display device DD. For example, the optical device may be a luminance sensor that measures brightness, a proximity sensor that measures distance, and/or a camera sensor. The optical device may use light of various wavelength bands. For example, the optical device may use visible light, infrared light, and/or ultraviolet light.

FIG. 1 illustrates that the display area DA includes one second display area DA2. However, embodiments are not necessarily limited thereto, and the display area DA may include two or more second display areas spaced apart from each other.

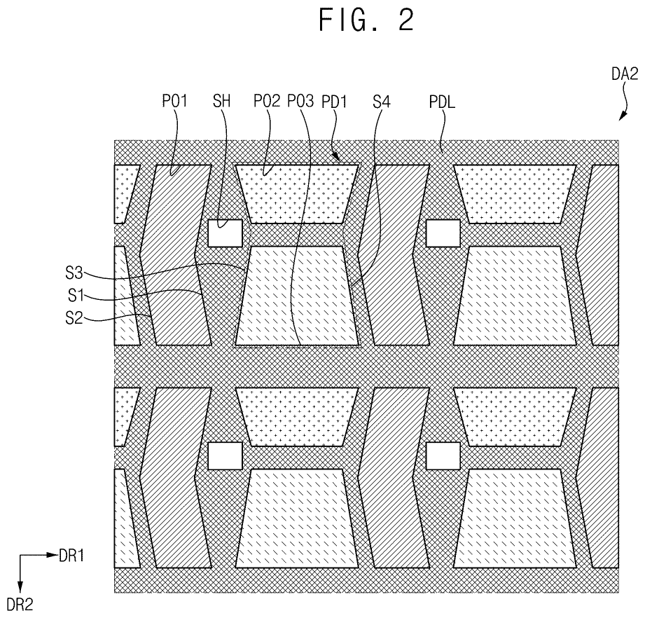

FIG. 2 is a plan view illustrating an example of a second display area of FIG. 1. FIG. 3 is a cross-sectional view illustrating the second display area of FIG. 2.

For example, FIG. 2 selectively illustrates an area in which four unit light emitting areas ULA forming a matrix of two rows and two columns are arranged among the second display area DA2, the unit light emitting areas ULA may be repeatedly defined along a first direction DR1 and a second direction DR2 in the entire second display area DA2.

In addition, for convenience of description, some of components illustrated in FIG. 3 are omitted or emphasized in FIG. 2. For example, emission layers EL1, EL2, and EL3, a common electrode CE, an encapsulation layer ENC, a touch sensing layer TSL, and an optical layer ARL illustrated in FIG. 3 are omitted in FIG. 2.

Referring to FIGS. 2 and 3, the display device DD may include a substrate SUB, first to fourth insulating layers IL1, IL2, IL3, and IL4, first to third driving elements TR1, TR2, and TR3, first to third light emitting elements LED1, LED2, and LED3, a pixel defining layer PDL, an encapsulation layer ENC, a touch sensing layer TSL, and an optical layer ARL.

The first driving element TR1 may include a first active pattern ACT1, a first gate electrode GE1, and a first signal electrode DE1, the second driving element TR2 may include a second active pattern ACT2, a second gate electrode GE2, and a second signal electrode DE2, and the third driving element TR3 may include a third active pattern ACT3, a third gate electrode GE3, and a third signal electrode DE3.

In addition, the first light emitting element LED1 may include a first pixel electrode PE1, a first emission layer EL1, and a common electrode CE, the second light emitting element LED2 may include a second pixel electrode PE2, a second emission layer EL2, and the common electrode CE, and the third light emitting element LED3 may include a third pixel electrode PE3, a third emission layer EL3, and the common electrode CE. The first to third light emitting elements LED1, LED2, and LED3 may be disposed in the second display area DA2 on the substrate SUB.

The substrate SUB may serve as a base of the display device DD. In an embodiment, examples of materials that can be used as the substrate SUB may include glass, quartz, plastic, or the like. These may be used alone or in combination with each other.

The first insulating layer IL1 may be disposed on the substrate SUB. The first insulating layer IL1 may prevent or reduce diffusion of impurities such as oxygen, moisture, or the like, to the first to third driving elements TR1, TR2, and TR3 from the substrate SUB. The first insulating layer IL1 may include an inorganic insulating material. Examples of the inorganic insulating material that can be used as the first insulating layer IL1 may include silicon oxide, silicon nitride, silicon oxynitride, or the like. These may be used alone or in combination with each other.

The first to third active patterns ACT1, ACT2, and ACT3 may be disposed on the first insulating layer IL1. In an embodiment, each of the first to third active patterns ACT1, ACT2, and ACT3 may include a silicon semiconductor material and/or an oxide semiconductor material. Examples of the silicon semiconductor material that can be used as the first to third active patterns ACT1, ACT2, and ACT3 may include amorphous silicon, polycrystalline silicon, or the like. Examples of the oxide semiconductor material that can be used as the first to third active patterns ACT1, ACT2, and ACT3 may include zinc oxide (ZnOx), gallium oxide (GaOx), tin oxide (SnOx), indium oxide (InOx), indium gallium oxide (IGO), indium zinc oxide (IZO), indium tin oxide (ITO), indium zinc tin oxide (IZTO), indium gallium zinc oxide (IGZO), or the like. These may be used alone or in combination with each other.

The second insulating layer IL2 may be disposed on the first insulating layer IL1. The second insulating layer IL2 may cover the first to third active patterns ACT1, ACT2, and ACT3. Optionally, the second insulating layer IL2 may be disposed in a pattern shape to expose a portion of each of the first to third active patterns ACT1, ACT2, and ACT3. The second insulating layer IL2 may include an inorganic insulating material. Examples of the inorganic insulating material that can be used as the second insulating layer IL2 may include silicon oxide, silicon nitride, silicon oxynitride, or the like. These may be used alone or in combination with each other.

The first to third gate electrodes GE1, GE2, and GE3 may be disposed on the second insulating layer IL2. In an embodiment, each of the first to third gate electrodes GE1, GE2, and GE3 may include a metal, an alloy, a conductive metal oxide, a transparent conductive material, or the like. These may be used alone or in combination with each other. The first gate electrode GE1 may overlap the first active pattern ACT1, the second gate electrode GE2 may overlap the second active pattern ACT2, and the third gate electrode GE3 may overlap the third active pattern ACT3.

The third insulating layer IL3 may be disposed on the second insulating layer IL2. In an embodiment, the third insulating layer IL3 may cover the first to third gate electrodes GE1, GE2, and GE3. The third insulating layer IL3 may include an inorganic insulating material. Examples of inorganic insulating materials that can be used as the third insulating layer IL3 may include silicon oxide, silicon nitride, silicon oxynitride, or the like. These may be used alone or in combination with each other.

The first to third signal electrodes DE1, DE2, and DE3 may be disposed on the third insulating layer IL3. The first to third signal electrodes DE1, DE2, and DE3 may be connected to the first to third active patterns ACT1, ACT2, and ACT3, respectively, through contact holes penetrating the second insulating layer IL2 and the third insulating layer IL3. For example, the first signal electrode DE1 may be connected to the first active pattern ACT1, the second signal electrode DE2 may be connected to the second active pattern ACT2, and the third signal electrode DE3 may be connected to the third active pattern ACT3. Each of the first to third signal electrodes DE1, DE2, and DE3 may include a metal, an alloy, a conductive metal oxide, a transparent conductive material, or the like. These may be used alone or in combination with each other.

The fourth insulating layer IL4 may be disposed on the third insulating layer IL3. The fourth insulating layer IL4 may cover the first to third signal electrodes DE1, DE2, and DE3. The fourth insulating layer IL4 may include an organic insulating material. Examples of the organic insulating material that can be used as the fourth insulating layer IL4 may include photoresist, polyacryl-based resin, polyimide-based resin, polyamide-based resin, siloxane-based resin, acrylic resin, epoxy-based resin, or the like. These may be used alone or in combination with each other. The fourth insulating layer IL4 may have a single-layer structure or a multi-layer structure including a plurality of insulating layers.

The first to third pixel electrodes PE1, PE2, and PE3 may be disposed on the fourth insulating layer IL4. Each of the first to third pixel electrodes PE1, PE2, and PE3 may include a metal, an alloy, a conductive metal oxide, a transparent conductive material, or the like. These may be used alone or in combination with each other.

The first to third pixel electrodes PE1, PE2, and PE3 may be connected to the first to third driving elements TR1, TR2, and TR3, respectively, through contact holes formed in the fourth insulating layer IL4.

The pixel defining layer PDL may be disposed on the fourth insulating layer IL4 and the first to third pixel electrodes PE1, PE2, and PE3. The pixel defining layer PDL may include an organic insulating material. Examples of the organic insulating material that can be used as the pixel defining layer PDL may include photoresist, polyacryl-based resin, polyimide-based resin, polyamide-based resin, siloxane-based resin, acrylic resin, epoxy-based resin, or the like. These may be used alone or in combination with each other.

In an embodiment, the pixel defining layer PDL may include a light blocking material. For example, the pixel defining layer PDL may appear substantially black. Examples of the light blocking material that can be used as the pixel defining layer PDL may include a black pigment, a black dye, a carbon black, or the like. These may be used alone or in combination with each other. Optionally, the pixel defining layer PDL may include a material in which an organic binder, a red pigment (or a red dye), a green pigment (or a green dye), and a blue pigment (or a blue dye) are mixed.

The pixel defining layer PDL may define a pixel opening exposing a portion of each of the first to third pixel electrodes PE1, PE2, and PE3. A light emitting area may be defined by the pixel opening. For example, the pixel defining layer PDL may define a first pixel opening PO1 exposing a portion of the first pixel electrode PE1, a second pixel opening PO2 exposing a portion of the second pixel electrode PE2, and a third pixel opening PO3 exposing a portion of the third pixel electrode PE3. A first light emitting area LA1 may be defined by the first pixel opening PO1, a second light emitting area LA2 may be defined by the second pixel opening PO2, and a third light emitting area LA3 may be defined by the third pixel opening PO3.

For example, each of the first to third light emitting areas LA1, LA2, and LA3 may be an area where light is emitted from the light emitting element. For example, the first light emitting area LA1 may be an area where light of a first color is emitted, the second light emitting area LA2 may be an area where light of a second color that is different from the first color is emitted, and the third light emitting area LA3 may be an area where light of a third color that is different from the first color and the second color is emitted. In an embodiment, the first color may be blue, the second color may be red, and the third color may be green. However, embodiments are not necessarily limited thereto.

The first to third pixel openings PO1, PO2, and PO3 may be repeatedly arranged along the first direction DR1 and the second direction DR2 in the second display area DA2. Accordingly, the second display area DA2 may include unit light emitting areas ULA repeatedly arranged along the first direction DR1 and the second direction DR2. For example, each of the unit light emitting areas ULA may be a combination of the first to third light emitting areas LA1, LA2, and LA3 adjacent to each other.

An arrangement structure of the first to third light emitting areas LA1, LA2, and LA3 may be an S-stripe structure. For example, an arrangement structure of the first to third pixel openings PO1, PO2, and PO3 may be the S-stripe structure. For example, the first pixel opening PO1 may be disposed in a first column, and the second pixel opening PO2 and the third pixel opening PO3 may be disposed in a second column adjacent to the first column. For example, the second pixel opening PO2 may be disposed in the first direction DR1 from the first pixel opening PO1, the third pixel opening PO3 may be disposed in the first direction DR1 from the first pixel opening PO1, and the second pixel opening PO2 and the third pixel opening PO3 may be arranged along the second direction DR2. In this case, one side of the second pixel opening PO2 and one side of the third pixel opening PO3 may face a long side (e.g., a first side S1) of the first pixel opening PO1.

The pixel defining layer PDL may further define a sensor hole SH. In an embodiment, the sensor hole SH may expose an insulating layer (e.g., the fourth insulating layer IL4) directly underneath the pixel defining layer PDL. The optical device SR may smoothly emit light through the sensor hole SH, or light may smoothly incident on the optical device SR. For example, even when the pixel defining layer PDL includes the light blocking material, light may smoothly travel through the sensor hole SH. As used herein, the term “smoothly” maybe used to describe light traveling without obstruction or diversion.

In a plan view, the sensor hole SH may be disposed with one pixel opening of the first to third pixel openings PO1, PO2, and PO3, on one side thereof and two remaining pixel openings of the first to third pixel openings PO1, PO2, and PO3, on another side thereof. For example, the first pixel opening PO1, the second pixel opening PO2, the third pixel opening PO3, and the sensor hole SH may be spaced apart from each other in a plan view. For example, the sensor hole SH might not overlap the first to third pixel openings PO1, PO2, and PO3 in a plan view. In other words, the sensor hole SH might not be disposed in the first to third light emitting areas LA1, LA2, and LA3.

In an embodiment, in a plan view, an area (or a size) (i.e., an aperture ratio) of the sensor hole SH may be less than an area (or a size) (i.e., an aperture ratio) of the first pixel opening PO1, an area (or a size) (i.e., an aperture ratio) of the second pixel opening PO2, and an area (or a size) (i.e., an aperture ratio) of the third pixel opening PO3.

In an embodiment, a shape of the sensor hole SH may be a square in a plan view. For example, the shape of the sensor hole SH may be a rectangle in a plan view. However, embodiments are not necessarily limited thereto, and the sensor hole SH may have various shapes in a plan view.

As illustrated in FIG. 2, the first pixel opening PO1 may have a first side S1 and a second side S2. The first side S1 may be adjacent to the sensor hole SH and may have a profile curving around the sensor hole SH in a plan view. Accordingly, the first pixel opening PO1 may have a concave shape with respect to a direction away from the sensor hole SH (i.e., a direction opposite to the first direction DR1) along the profile of the first side S1 in a plan view.

The second side S2 may be opposite to the first side S1. For example, in a plan view, the second side S2 may be spaced apart from the sensor hole SH in the first direction DR1 with the first side S1 therebetween. In an embodiment, a profile of the second side S2 may be substantially same as the profile of the first side S1 in a plan view. Accordingly, the first pixel opening PO1 may have a convex shape with respect to a direction away from the sensor hole SH (i.e., the direction opposite to the first direction DR1) along the profile of the second side S2 in a plan view.

In an embodiment, in a plan view, a degree to which the first pixel opening PO1 is concave in the direction away from the sensor hole SH along the profile of the first side S1 may be substantially same as a degree to which the first pixel opening PO1 is convex in the direction away from the sensor hole SH along the profile of the second side S2. For example, the shape of the first pixel opening PO1 may be a chevron in a plan view. However, embodiments are not necessarily limited thereto.

As illustrated in FIG. 2, a first planar figure PD1 defined along sides of the second pixel opening PO2 and sides of the third pixel opening PO3 may have a third side S3 and a fourth side S4. For example, the first planar figure PD1 may be an imaginary figure defined by an imaginary line extending along the sides of the second pixel opening PO2 and the sides of the third pixel opening PO3. In the present specification, the first planar figure PD1 may also be referred to as a planar figure or a second planar figure.

In an embodiment, the third side S3 may be adjacent to the sensor hole SH and may have a profile curving around the sensor hole SH in a plan view. Accordingly, the first planar figure PD1 may have a concave shape with respect to a direction away from the sensor hole SH (i.e., the first direction DR1) along the profile of the third side S3 in a plan view.

In a plan view, the first side S1 of the first pixel opening PO1 and the third side S3 of the first planar figure PD1 may face each other in the first direction DR1 with the sensor hole SH therebetween in a plan view. For example, the sensor hole SH may be disposed between the first side S1 of the first pixel opening PO1 and the third side S3 of the first planar figure PD1 in a plan view.

The fourth side S4 may be opposite to the third side S3. For example, in a plan view, the fourth side S4 may be spaced apart from the sensor hole SH in the first direction DR1 with the third side S3 therebetween. In an embodiment, a profile of the fourth side S4 may be mirror symmetrical to the profile of the third side S3 in a plan view. For example, the profile of the fourth side S4 may be mirror symmetrical to the profile of the third side S3 with respect to an imaginary reference line extending in the second direction DR2 in a plan view. Accordingly, the first planar figure PD1 may have a concave shape with respect to a direction closer to the sensor hole SH (i.e., the direction opposite to the first direction DR1) along the profile of the fourth side S4 in a plan view.

In an embodiment, in a plan view, a degree to which the first planar figure PD1 is concave in the direction away from the sensor hole SH along the profile of the third side S3 may be substantially same as a degree to which the first planar figure PD1 is concave in the direction closer to the sensor hole SH along the profile of the fourth side S4. For example, a shape of the second pixel opening PO2 may be an equilateral trapezoid of which width becomes narrower as approaching one side in the second direction DR2 thereof, and a shape of the third pixel opening PO3 may be an equilateral trapezoid of which width becomes wider as approaching one side in the second direction DR2 thereof. However, embodiments are not necessarily limited thereto.

The first emission layer EL1 may be disposed on the first pixel electrode PE1 exposed by the first pixel opening PO1. For example, the first emission layer EL1 may be disposed in the first light emitting area LA1. The first emission layer EL1 may emit light of the first color. For example, the first emission layer EL1 may include a first emission material that emits light of the first color. In an embodiment, the first color may be blue. However, embodiments are not necessarily limited thereto. The first emission material may include an organic emission material and/or an inorganic emission material.

The second emission layer EL2 may be disposed on the second pixel electrode PE2 exposed by the second pixel opening PO2. For example, the second emission layer EL2 may be disposed in the second light emitting area LA2. The second emission layer EL2 may emit light of the second color. For example, the second emission layer EL2 may include a second emission material that emits light of the second color. In an embodiment, the second color may be red. However, embodiments are not necessarily limited thereto. The second emission material may include an organic emission material and/or an inorganic emission material.

The third emission layer EL3 may be disposed on the third pixel electrode PE3 exposed by the third pixel opening PO3. For example, the third emission layer EL3 may be disposed in the third light emitting area LA3. The third emission layer EL3 may emit light of the third color. For example, the third emission layer EL3 may include a third emission material that emits light of the third color. In an embodiment, the third color may be green. However, embodiments are not necessarily limited thereto. The third emission material may include an organic emission material and/or an inorganic emission material.

In an embodiment, functional layers such as a hole injection layer, a hole transport layer, an electron transport layer, an electron injection layer, or the like may be disposed on and/or under each of the first to third emission layers EL1, EL2, and EL3.

The common electrode CE may be disposed on the fourth insulating layer IL4, the pixel defining layer PDL, and the first to third emission layers EL1, EL2, and EL3. In an embodiment, the common electrode CE may continuously extend in the light emitting areas LA1, LA2, and LA3. The common electrode CE may include a conductive material such as a metal, an alloy, a conductive metal nitride, a conductive metal oxide, a transparent conductive material, or the like. These may be used alone or in combination with each other. For example, the common electrode CE may include a transparent conductive oxide such as IGO, IZO, ITO, IZTO, IGZO, or the like. In addition, the common electrode CE may include a semi-transparent layer including a metal. For example, the common electrode CE may include a semi-transparent layer including a silver-magnesium alloy. However, embodiments are not necessarily limited thereto. The common electrode CE may have a single-layer structure or a multi-layer structure including a plurality of conductive layers.

FIG. 3 illustrates that the common electrode CE is also disposed at a position corresponding to the sensor hole SH. However, embodiments are not necessarily limited thereto, and the common electrode CE might not be disposed at the position corresponding to the sensor hole SH. For example, the common electrode CE may define a through hole at the position corresponding to the sensor hole SH.

As a result, the first light emitting element LED1 including the first pixel electrode PE1, the first emission layer EL1, and the common electrode CE may be disposed in the first light emitting area LA1. In an embodiment, the first light emitting element LED1 may emit light of the first color. In addition, the second light emitting element LED2 including the second pixel electrode PE2, the second emission layer EL2, and the common electrode CE may be disposed in the second light emitting area LA2. In an embodiment, the second light emitting element LED2 may emit light of the second color. In addition, the third light emitting element LED3 including the third pixel electrode PE3, the third emission layer EL3, and the common electrode CE may be disposed in the third light emitting area LA3. In an embodiment, the third light emitting element LED3 may emit light of the third color.

The encapsulation layer ENC may be disposed on the common electrode CE. In an embodiment, the encapsulation layer ENC may prevent or reduce impurities such as moisture from penetrating into the first to third light emitting elements LED1, LED2, and LED3. In an embodiment, the encapsulation layer ENC may include a first inorganic encapsulation layer disposed on the common electrode CE, an organic encapsulation layer disposed on the first inorganic encapsulation layer, and a second inorganic encapsulation layer disposed on the organic encapsulation layer.

The touch sensing layer TSL may be disposed on the encapsulation layer ENC. The touch sensing layer TSL may include a plurality of touch electrode arrays for detecting a user's handling in a capacitive manner, a touch pad portion, and a plurality of touch wires electrically connecting the touch pad portion and the touch electrode arrays. For example, the touch sensing layer TSL may detect the user's touch in a self-capacitance manner or a mutual capacitance manner. However, embodiments are not necessarily limited thereto. In an embodiment, the touch sensing layer TSL may be omitted.

The optical layer ARL may be disposed on the touch sensing layer TSL. The optical layer ARL may reduce reflection of external light incident on the display device DD. In an embodiment, the optical layer ARL may include a plurality of color filters and a black matrix. In this case, the black matrix may define a through hole at a position corresponding to the sensor hole SH of the pixel defining layer PDL.

The optical device SR may be disposed under the substrate SUB. For example, the optical device SR may be disposed under the substrate SUB to correspond to the sensor hole SH. The optical device SR might not overlap the first to third light emitting elements LED1, LED2, and LED3. The optical device SR may emit or receive light. In an embodiment, the optical device SR may be an optical sensor that detects light incident on the display device DD. For example, the optical device SR may be a luminance sensor that measures brightness, a proximity sensor that measures distance, and/or a camera sensor. The optical device SR may use light of various wavelength bands. For example, the optical device SR may use visible light, infrared light, and/or ultraviolet light.

For example, when the optical device SR is the luminance sensor, the optical device SR may detect a luminance of an ambient light of the display device DD. The display device DD may control operation of elements constituting the display device DD according to a luminance information detected by the optical device SR. For example, the display device DD may increase a luminance of light emitted from the light emitting elements when the luminance of the ambient light is high, and may decrease the luminance of light emitted from the light emitting elements when the luminance of the ambient light is low.

For example, when the optical device SR is the proximity sensor, the optical device SR may detect an object around the display device DD. The display device DD may control the operation of the elements constituting the display device DD according to an information detected by the optical device SR. For example, when the display device DD is a mobile phone and the display device DD detects, through the optical device SR, that a user places the display device DD near his/her ear to call, the display device DD may reduce a power consumption thereof by preventing the light emitting elements from emitting light.

In a case where the arrangement structure of the first to third pixel openings PO1, PO2, and PO3 defining the light emitting areas is the S-stripe structure, a long side (i.e., the first side S1) of the first pixel opening PO1 in the first row and one side of each of the second and third pixel openings PO2 and PO3 in the second row may face each other. If the long side of the first pixel opening PO1 and the side of each of the second and third pixel openings PO2 and PO3 extend parallel to each other, a gap between the pixel openings PO1, PO2, and PO3 may be narrow. Accordingly, a space for forming the sensor hole SH of the pixel defining layer PDL might not be secured. For example, if each of the first to third pixel openings PO1, PO2, and PO3 has a substantially rectangular shape in a plan view, the space for forming the sensor hole SH of the pixel defining layer PDL between the pixel openings PO1, PO2, and PO3 might not be sufficiently secured.

In the display device DD, according to embodiments, the first side S1 of the first pixel opening PO1 may be adjacent to the sensor hole SH and may have the profile curving around the sensor hole SH in a plan view. Accordingly, the first pixel opening PO1 may have the concave shape with respect to a direction away from the sensor hole SH along the profile of the first side S1 in a plan view. In addition, the first planar figure PD1 defined by the imaginary line extending along the sides of the second pixel opening PO2 and the sides of the third pixel opening PO3 may have the third side S3 that faces the first side S1 of the first pixel opening POI with the sensor hole SH therebetween, the third side S3 of the first planar figure PD1 may be adjacent to the sensor hole SH, and the third side S3 of the first planar figure PD1 may have the profile curving around the sensor hole SH in a plan view. Accordingly, the first planar figure PD1 may have the concave shape with respect to a direction away from the sensor hole SH along the profile of the third side S3 in a plan view. Accordingly, compared to a case where the long side of the first pixel opening PO1 and the side of each of the second and third pixel openings PO2 and PO3 extend parallel to each other, a gap between the pixel openings PO1, PO2, and PO3 may be wide Accordingly, the space for forming the sensor hole SH of the pixel defining layer PDL between the pixel openings PO1, PO2, and PO3 may be sufficiently secured.

For example, according to embodiments, even when the arrangement structure of the first to third pixel openings PO1, PO2, and PO3 defining the light emitting areas is the S-stripe structure, the sensor hole SH of the pixel defining layer PDL required for utilizing the optical device SR may be more easily formed. Accordingly, the display device DD may be more easily designed.

In addition, in the display device DD according to embodiments, the first pixel opening PO1 may further have the second side S2 opposite to the first side S1, and the profile of the second side S2 may be substantially same as the profile of the first side S1 in a plan view. For example, the first pixel opening PO1 may have the convex shape with respect to a direction away from the sensor hole SH along the profile of the second side S2 in a plan view. Accordingly, in a plan view, the degree to which the first pixel opening PO1 is concave in the direction away from the sensor hole SH along the profile of the first side S1 may be substantially same as the degree to which the first pixel opening PO1 is convex in the direction away from the sensor hole SH along the profile of the second side S2.

In addition, the first planar figure PD1 may further have the fourth side S4 opposite to the third side S3, and the profile of the fourth side S4 may be mirror symmetrical to the profile of the third side S3 in a plan view. For example, the first planar figure PD1 may have the concave shape with respect to a direction closer to the sensor hole SH along the profile of the fourth side S4 in a plan view. Accordingly, in a plan view, the degree to which the first planar figure PD1 is concave in the direction away from the sensor hole SH along the profile of the third side S3 may be substantially same as the degree to which the first planar figure PD1 is concave in the direction closer to the sensor hole SH along the profile of the fourth side S4.

Accordingly, compared to a case where the long side of the first pixel opening PO1 and the side of each of the second and third pixel openings PO2 and PO3 extend parallel to each other, an area (or a size) (i.e., an aperture ratio) of each of the first to third pixel openings PO1, PO2, and PO3 might not be reduced in a plan view. For example, compared to a case where each of the first to third pixel openings PO1, PO2, and PO3 has a substantially rectangular shape in a plan view, an area (or a size) (i.e., an aperture ratio) of each of the first to third pixel openings PO1, PO2, and PO3 might not be reduced in a plan view. For example, according to embodiments, the display device DD may be more easily designed without reducing an efficiency of light emitted from the light emitting elements.

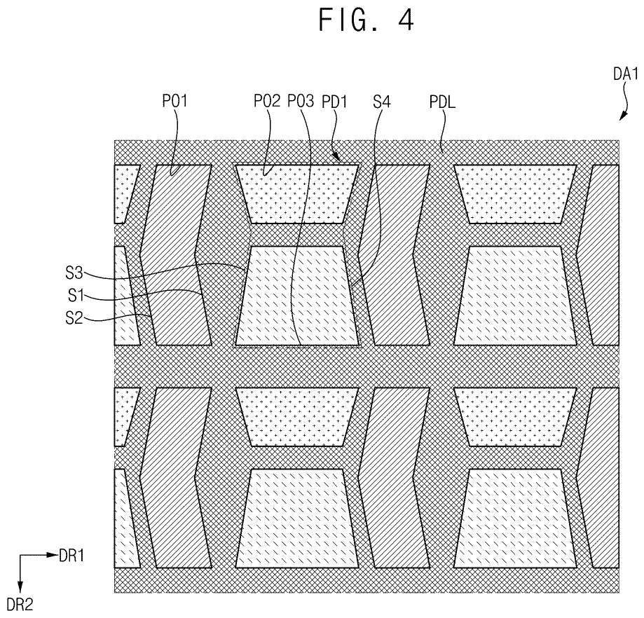

FIG. 4 is a plan view illustrating an example of a first display area of FIG. 1.

Referring further to FIG. 4, similarly to the second display area DA2 of FIG. 2, the first to third pixel openings PO1, PO2, and PO3 may be repeatedly arranged along the first direction DR1 and the second direction DR2 in the first display area DA1. Accordingly, the first display area DA1 may include unit light emitting areas ULA (refer to FIGS. 2 and 3) repeatedly arranged along the first direction DR1 and the second direction DR2.

For example, characteristics (e.g., planar shape, size, arrangement, or the like) of the pixel openings defined in the first display area DA1 may be substantially same as characteristics (e.g., planar shape, size, arrangement, or the like) of the pixel openings defined in the second display area DA2. Accordingly, a gap between the pixel openings may be maintained constant even at positions where the first display area DA1 and the second display area DA2 are adjacent to each other. In addition, a deviation of luminance or the like due to differences of structure between the first display area DA1 and the second display area DA2 may be reduced or prevented. Accordingly, a visibility of the display device DD might not be reduced.

In an embodiment, the sensor hole SH (refer to FIG. 2) might not be defined in the first display area DA1. For example, since the optical sensor SR (refer to FIG. 3) is not disposed in the first display area DA1, the sensor hole SH might not be defined in the first display area DA1. Even when the sensor hole SH is not defined in the first display area DA1, the first to third pixel openings PO1, PO2, and PO3 may be repeatedly arranged in the first display area DA1. For example, even when the sensor hole SH is not defined in the first display area DA1, the characteristics (e.g., planar shape, size, arrangement, or the like) of the pixel openings defined in the first display area DA1 may be substantially same as the characteristics (e.g., planar shape, size, arrangement, or the like) of the pixel openings defined in the second display area DA2.

Although FIG. 4 illustrates that the sensor hole SH is not defined in the first display area DA, embodiments are not necessarily limited thereto. Optionally, the sensor hole SH may be defined in the first display area DA1 as in the second display area DA2. Accordingly, the deviation of luminance or the like due to the differences of structure between the first display area DA1 and the second display area DA2 may be reduced or prevented.

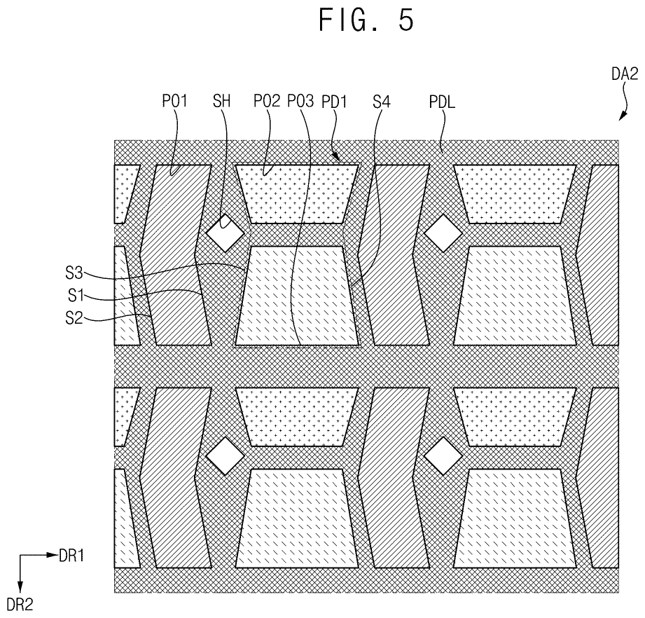

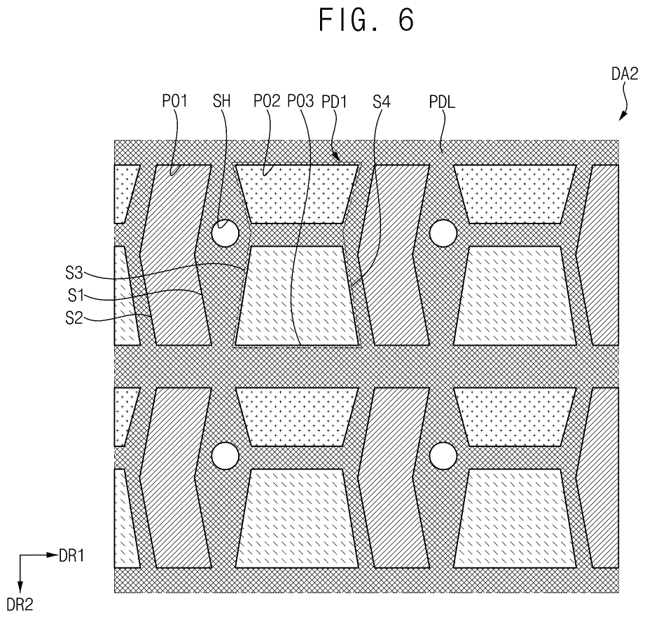

FIG. 5 and FIG. 6 are plan views illustrating another examples of the second display area of FIG. 1. For example, each of FIG. 5 and FIG. 6 may correspond to FIG. 2.

The second display area DA2, according to embodiments described below with reference to FIGS. 5 and 6, may be substantially same as or similar to the second display area DA2 according to embodiments described above with reference to FIG. 2 except for a shape of the sensor hole SH in a plan view. Therefore, to the extent that an element is not described in detail with respect to this figure, it may be understood that the element is at least similar to a corresponding element that has been described elsewhere within the present disclosure.

Referring to FIG. 5, in an embodiment, the shape of the sensor hole SH may be a rhombus in a plan view. In addition, referring to FIG. 6, in an embodiment, the shape of the sensor hole SH may be a circle in a plan view. However, embodiments are not necessarily limited thereto, and the sensor hole SH may have various shapes in a plan view.

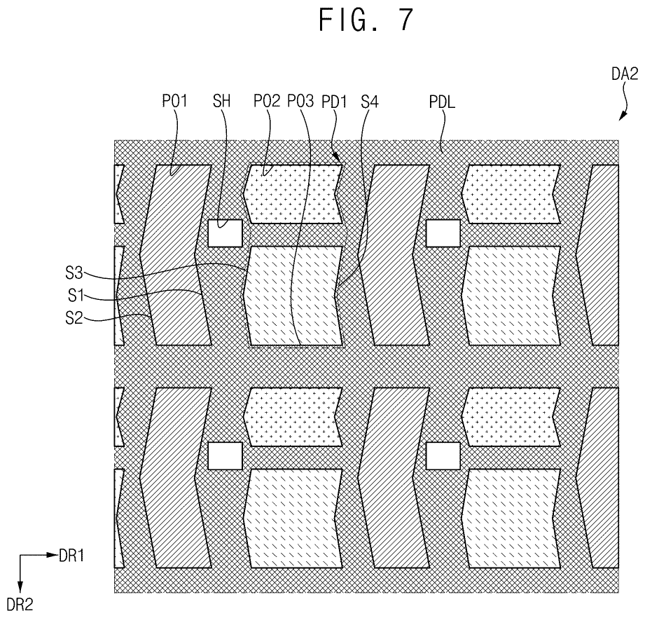

FIG. 7 is a plan view illustrating an example of the second display area of FIG. 1.

The second display area DA2, according to embodiments described below with reference to FIG. 7, may be substantially same as or similar to the second display area DA2 according to embodiments described above with reference to FIG. 2 except for a shape of each of the second pixel opening PO2 and the third pixel opening PO3 in a plan view. Therefore, to the extent that an element is not described in detail with respect to this figure, it may be understood that the element is at least similar to a corresponding element that has been described elsewhere within the present disclosure.

Referring to FIG. 7, the pixel defining layer PDL may define the first pixel opening PO1 exposing a portion of the first pixel electrode PE1, the second pixel opening PO2 exposing a portion of the second pixel electrode PE2, and the third pixel opening PO3 exposing a portion of the third pixel electrode PE3. The first to third pixel openings PO1, PO2, and PO3 may be repeatedly arranged along the first direction DR1 and the second direction DR2 in the second display area DA2.

As illustrated in FIG. 7, a first planar region PD1 defined along sides of the second pixel opening PO2 and sides of the third pixel opening PO3 may have a third side S3 and a fourth side S4.

In an embodiment, the third side S3 may be adjacent to the sensor hole SH and may have a profile curving around the sensor hole SH in a plan view. Accordingly, the first planar region PD1 may have a concave shape with respect to a direction away from the sensor hole SH (i.e., the first direction DR1) along the profile of the third side S3 in a plan view.

Accordingly, even when the arrangement structure of the first to third pixel openings PO1, PO2, and PO3 defining the light emitting areas is the S-stripe structure, the sensor hole SH of the pixel defining layer PDL required for utilizing the optical device SR may be more easily formed. Accordingly, the display device DD may be more easily designed.

The fourth side S4 may be opposite to the third side S3. For example, in a plan view, the fourth side S4 may be spaced apart from the sensor hole SH in the first direction DR1 with the third side S3 therebetween. In an embodiment, a profile of the fourth side S4 may be substantially same as the profile of the third side S3 in a plan view. Accordingly, the first planar figure PD1 may have a convex shape with respect to a direction away from the sensor hole SH (i.e., the first direction DR1) along the profile of the fourth side S4 in a plan view.

In an embodiment, in a plan view, a degree to which the first planar figure PD1 is concave in the direction away from the sensor hole SH along the profile of the third side S3 may be substantially same as a degree to which the first planar figure PD1 is convex in the direction away from the sensor hole SH along the profile of the fourth side S4.

Accordingly, compared to a case where the long side of the first pixel opening PO1 and the side of each of the second and third pixel openings PO2 and PO3 extend parallel to each other, an area (or a size) (i.e., an aperture ratio) of each of the first to third pixel openings PO1, PO2, and PO3 might not be reduced in a plan view. For example, compared to a case where each of the first to third pixel openings PO1, PO2, and PO3 has a substantially rectangular shape in a plan view, an area (or a size) (i.e., an aperture ratio) of each of the first to third pixel openings PO1, PO2, and PO3 might not be reduced in a plan view. For example, the shape of each of the second pixel opening PO2 and the third pixel opening PO3 may be a chevron in a plan view. However, embodiments are not necessarily limited thereto.

When the first to third pixel openings PO1, PO2, and PO3 of FIG. 7 are repeatedly arranged in the second display area DA2, the first to third pixel openings PO1, PO2, and PO3 of FIG. 7 may also be repeatedly arranged in the first display area DA1 along the first direction DR1 and the second direction DR2. For example, even in the embodiments described above with reference to FIG. 7, the characteristics (e.g., planar shape, size, arrangement, or the like) of the pixel openings defined in the first display area DA1 may be substantially same as the characteristics (e.g., planar shape, size, arrangement, or the like) of the pixel openings defined in the second display area DA2.

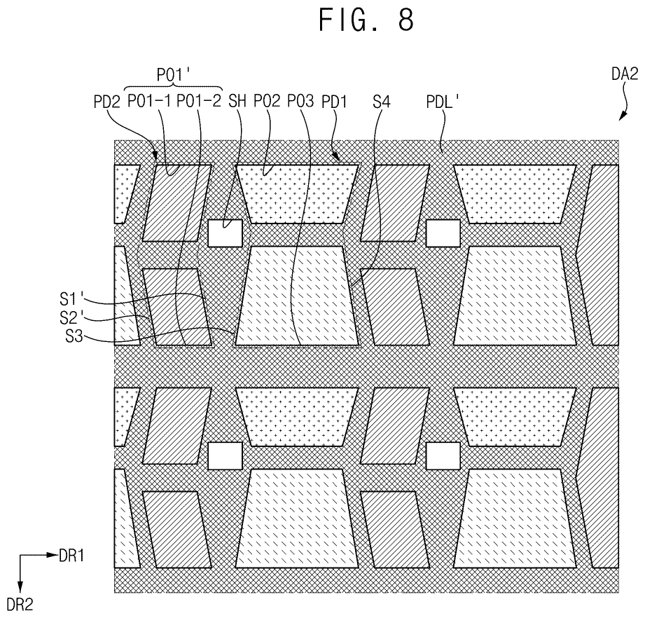

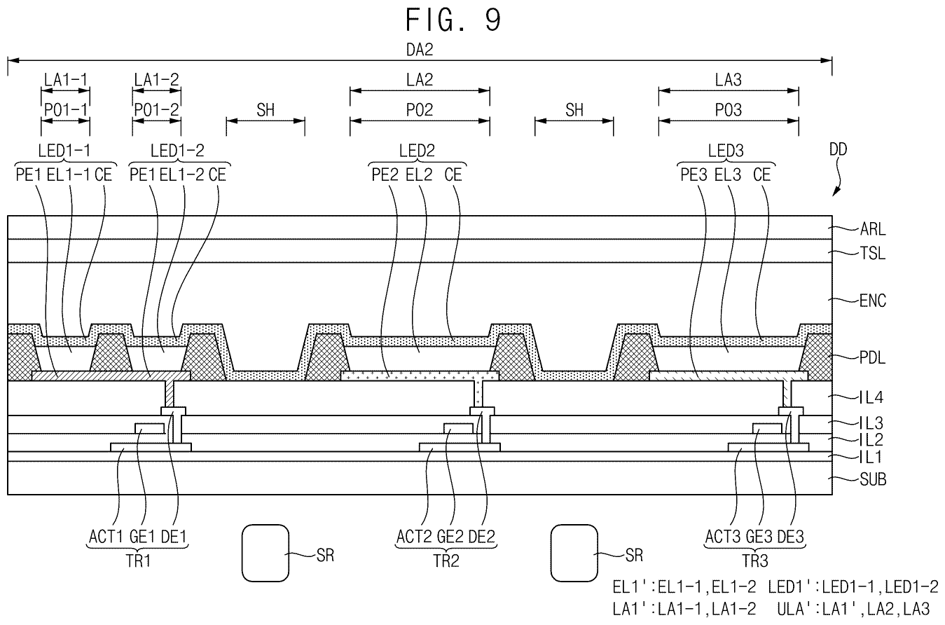

FIG. 8 is a plan view illustrating an example of the second display area of FIG. 1. FIG. 9 is a cross-sectional view illustrating the second display area of FIG. 8.

The second display area DA2, according to embodiments described below with reference to FIGS. 8 and 9, may be substantially same as or similar to the second display area DA2 according to embodiments described above with reference to FIG. 2 except that a pixel defining layer PDL′ defines a first pixel opening PO1′ having a divided structure. Therefore, to the extent that an element is not described in detail with respect to this figure, it may be understood that the element is at least similar to a corresponding element that has been described elsewhere within the present disclosure.

Referring to FIGS. 8 and 9, the pixel defining layer PDL′ may define the first pixel opening PO1′ exposing a portion of the first pixel electrode PE1, a second pixel opening PO2 exposing a portion of the second pixel electrode PE2, and a third pixel opening PO3 exposing a portion of the third pixel electrode PE3. A first light emitting area LA1′ may be defined by the first pixel opening PO1′, a second light emitting area LA2 may be defined by the second pixel opening PO2, and a third light emitting area LA3 may be defined by the third pixel opening PO3.

The first light emitting area LA1′ may be an area where light of the first color is emitted, the second light emitting area LA2 may be an area where light of the second color is emitted, and the third light emitting area LA3 may be an area where light of the third color is emitted. In an embodiment, the first color may be blue, the second color may be red, and the third color may be green. However, embodiments are not necessarily limited thereto.

The first to third pixel openings PO1′, PO2, and PO3 may be repeatedly arranged along the first direction DR1 and the second direction DR2 in the second display area DA2. Accordingly, the second display area DA2 may include unit light emitting areas ULA′ repeatedly arranged along the first direction DR1 and the second direction DR2. For example, each of the unit light emitting areas ULA′ may be a combination of the first to third light emitting areas LA1′, LA2, and LA3 adjacent to each other.

An arrangement structure of the first to third light emitting areas LA1′, LA2, and LA3 may be an S-stripe structure. For example, an arrangement structure of the first to third pixel openings PO1′, PO2, and PO3 may be the S-stripe structure. For example, the first pixel opening PO1′ may be disposed in a first column, and the second pixel opening PO2 and the third pixel opening PO3 may be disposed in a second column adjacent to the first column. For example, the second pixel opening PO2 may be disposed in the first direction DR1 from the first pixel opening PO1′, the third pixel opening PO3 may be disposed in the first direction DR1 from the first pixel opening PO1′, and the second pixel opening PO2 and the third pixel opening PO3 may be arranged along the second direction DR2.

In an embodiment, the first pixel opening PO1′ may include a first sub-pixel opening PO1-1 and a second sub-pixel opening PO1-2. The first sub-pixel opening PO1-1 and the second sub-pixel opening PO1-2 may be arranged along the second direction DR2. For example, the first pixel opening PO1′ may have a structure divided into the first sub-pixel opening PO1-1 and the second sub-pixel opening PO1-2. For example, as illustrated in FIG. 9, the pixel defining layer PDL′ may be disposed adjacent to a central portion of the first pixel electrode PE1. Accordingly, the first pixel opening PO1′ may have a divided structure. The first sub-pixel opening PO1-1 may expose a first portion of the first pixel electrode PE1, and the second sub-pixel opening PO1-2 may expose a second portion of the first pixel electrode PE1.

Accordingly, the first light emitting area LA1′ may have a structure divided into a first sub-light emitting area LA1-1 and a second sub-light emitting area LA1-2. For example, the first sub-light emitting area LA1-1 may be defined by the first sub-pixel opening PO1-1, and the second sub-light emitting area LA1-2 may be defined by the second sub-pixel opening PO1-2. Each of the first sub-light emitting area LA1-1 and the second sub-light emitting area LA1-2 may be an area where light of the first color is emitted.

In addition, a first emission layer EL1′ may include a first sub-emission layer EL1-1 and a second sub-emission layer EL1-2. The first sub-emission layer EL1-1 may be disposed on the first portion of the first pixel electrode PE1 exposed by the first sub-pixel opening PO1-1, and the second sub-emission layer EL1-2 may be disposed on the second portion of the first pixel electrode PE1 exposed by the second sub-pixel opening PO1-2. For example, the first sub-emission layer EL1-1 may be disposed in the first sub-light emitting area LA1-1, and the second sub-emission layer EL1-2 may be disposed in the second sub-light emitting area LA1-2. The first sub-emission layer EL1-1 and the second sub-emission layer EL1-2 may emit light of the first color.

As a result, a first light emitting element LED1′ may have a structure divided into a first sub-light emitting element LED1-1 and a second sub-light emitting element LED1-2. For example, the first sub-light emitting element LED1-1 including the first portion of the first pixel electrode PE1, the first sub-emission layer EL1-1, and the common electrode CE may be disposed in the first sub-light emitting area LA1-1. In addition, the second sub-light emitting element LED1-2 including the second portion of the first pixel electrode PE1, the second sub-emission layer EL1-2, and the common electrode CE may be disposed in the second sub-light emitting area LA1-2. Each of the first sub-light emitting element LED1-1 and the second sub-light emitting element LED1-2 may emit light of the first color.

As illustrated in FIG. 8, a second planar figure PD2 defined along sides of the first sub-pixel opening PO1-1 and sides of the second sub-pixel opening PO1-2 may have a first side S1′ and a second side S2′. For example, the second planar figure PD2 may be an imaginary figure defined by an imaginary line extending along the sides of the first sub-pixel opening PO1-1 and the sides of the second sub-pixel opening PO1-2. In the present specification, the second planar figure PD2 may also be referred to as a first planar figure.

The first side S1′ may be adjacent to the sensor hole SH and may have a profile curving around the sensor hole SH in a plan view. Accordingly, the second planar figure PD2 may have a concave shape with respect to a direction away from the sensor hole SH (i.e., the first direction DR1) along the profile of the first side S1′ in a plan view.

The second side S2′ may be opposite to the first side S1′. For example, in a plan view, the second side S2′ may be spaced apart from the sensor hole SH in the first direction DR1 with the first side S1′ therebetween. In an embodiment, a profile of the second side S2′ may be substantially same as the profile of the first side S1′ in a plan view. Accordingly, the second planar figure PD2 may have a convex shape with respect to a direction away from the sensor hole SH (i.e., the direction opposite to the first direction DR1) along the profile of the second side S2′ in a plan view.

In an embodiment, in a plan view, a degree to which the second planar figure PD2 is concave in the direction away from the sensor hole SH along the profile of the first side S1′ may be substantially same as a degree to which the second planar figure PD2 is convex in the direction away from the sensor hole SH along the profile of the second side S2′. For example, a shape of the second planar figure PD2 may be a chevron in a plan view. However, embodiments are not necessarily limited thereto.

In the display device DD, according to embodiments, even when the first pixel opening PO1′ has a structure divided into the first sub-pixel opening PO1-1 and the second sub-pixel opening PO1-2, the second planar figure PD2 defined by the imaginary line extending along the sides of the first sub-pixel opening PO1-1 and the sides of the second sub-pixel opening PO1-2 may have the first side S1′ adjacent to the sensor hole SH, and the first side S1′ may have the profile curving around the sensor hole SH in a plan view. Accordingly, the second planar figure PD2 may have the concave shape with respect to a direction away from the sensor hole SH along the profile of the first side S1′ in a plan view. Accordingly, a space for forming the sensor hole SH of the pixel defining layer PDL′ between the pixel openings PO1′, PO2, and PO3 may be sufficiently secured. Accordingly, even when the arrangement structure of the first to third pixel openings PO1′, PO2, and PO3 defining the light emitting areas is the S-stripe structure, the sensor hole SH of the pixel defining layer PDL′ required for utilizing the optical device SR may be more easily formed. Accordingly, the display device DD may be more easily designed.

In particular, since the first pixel opening PO1′ has a structure divided into the first sub-pixel opening PO1-1 and the second sub-pixel opening PO1-2, an area (or volume) of the pixel defining layer PDL′ between the pixel openings PO1′, PO2, and PO3 may be further increased. Accordingly, the space for forming the sensor hole SH may be more easily secured.

When the first to third pixel openings PO1′, PO2, and PO3 of FIG. 8 are repeatedly arranged in the second display area DA2, the first to third pixel openings PO1′, PO2, and PO3 of FIG. 8 may also be repeatedly arranged in the first display area DA1 along the first direction DR1 and the second direction DR2. For example, even in the embodiments described above with reference to FIG. 8, the characteristics (e.g., planar shape, size, arrangement, or the like) of the pixel openings defined in the first display area DA1 may be substantially same as the characteristics (e.g., planar shape, size, arrangement, or the like) of the pixel openings defined in the second display area DA2.

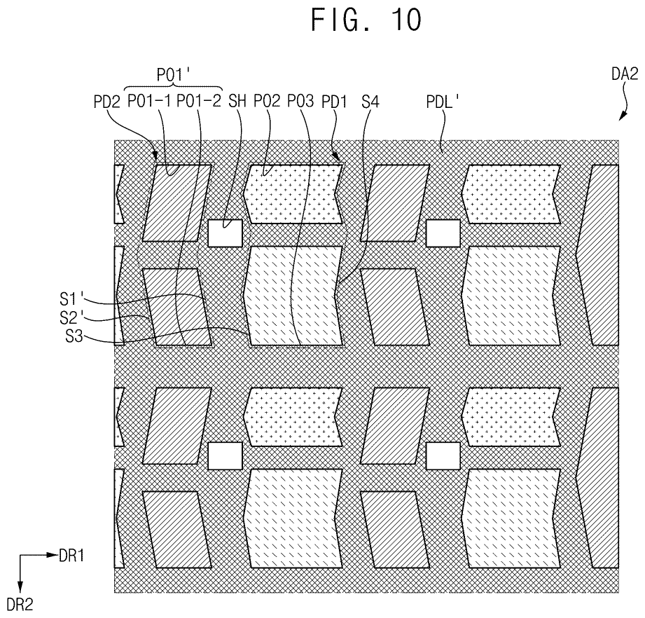

FIG. 10 is a plan view illustrating an example of the second display area of FIG. 1.

The second display area DA2, according to embodiments described below with reference to FIG. 10, may be substantially same as or similar to the second display area DA2 according to embodiments described above with reference to FIG. 8 except for a shape of each of the second pixel opening PO2 and the third pixel opening PO3 in a plan view. In addition, same description as described above with reference to FIG. 7 may be applied to a shape of each of the second pixel opening PO2 and the third pixel opening PO3 in a plan view of FIG. 10. Therefore, to the extent that an element is not described in detail with respect to this figure, it may be understood that the element is at least similar to a corresponding element that has been described elsewhere within the present disclosure.

Referring to FIG. 10, in an embodiment, even when the first pixel opening PO1′ has a structure divided into the first sub-pixel opening PO1-1 and the second sub-pixel opening PO1-2, each of the second pixel opening PO2 and the third pixel opening PO3 may have the same planar shape as the planar shape described with reference to FIG. 7.

For example, the shape of the second planar figure PD2 defined along the sides of the first sub-pixel opening PO1-1 and the sides of the second sub-pixel opening PO1-2, the shape of the second pixel opening PO2, and the shape of the third pixel opening PO3 may all be a chevron shape in a plan view. However, embodiments are not necessarily limited thereto.

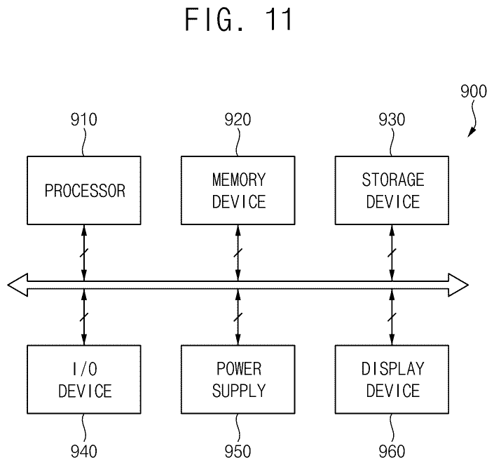

FIG. 11 is a block diagram illustrating an electronic device according to an embodiment. Referring to FIG. 11, in an embodiment, an electronic device 900 may include a

processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

Although embodiments and implementations have been described herein, other embodiments and modifications will be apparent from this description. Accordingly, the invention is not necessarily limited to such embodiments, but rather to the broader scope of the appended claims and various obvious modifications and equivalent arrangements as would be apparent to a person of ordinary skill in the art.

What is claimed is:

1. A display device, comprising:
a substrate;
first to third pixel electrodes disposed on the substrate; and
a pixel defining layer including a first pixel opening, a second pixel opening, a third pixel opening, and a sensor hole, the first pixel opening exposing a portion of the first pixel electrode, the second pixel opening exposing a portion of the second pixel electrode, the third pixel opening exposing a portion of the third pixel electrode, and the sensor hole being disposed with one pixel opening of the first to third pixel openings on one side thereof and two remaining pixel openings of the first to third pixel openings on another side thereof,
wherein the first pixel opening includes a first side adjacent to the sensor hole, and a profile of the first side curves around the sensor hole in a plan view, and
wherein the first pixel opening has a concave shape with respect to a direction away from the sensor hole, along the profile of the first side in the plan view.

2. The display device of claim 1, wherein the first pixel opening further includes a second side that is opposite to the first side, and a profile of the second side is the same as the profile of the first side in the plan view.

3. The display device of claim 2, wherein the first pixel opening has a convex shape with respect to the direction away from the sensor hole along the profile of the second side in the plan view.

4. The display device of claim 1, wherein a planar region defined along sides of the second pixel opening and sides of the third pixel opening has a third side adjacent to the sensor hole, and a profile of the third side curves around the sensor hole in the plan view, and
wherein the planar region has a concave shape with respect to the direction away from the sensor hole along the profile of the third side in the plan view.

5. The display device of claim 4, wherein in the plan view, the first side of the first pixel opening and the third side of the planar region face each other in a first direction with the sensor hole interposed therebetween.

6. The display device of claim 5, wherein the second pixel opening is disposed in the first direction from the first pixel opening,
wherein the third pixel opening is disposed in the first direction from the first pixel opening, and
wherein the second pixel opening and the third pixel opening are disposed along a second direction that is perpendicular to the first direction.

7. The display device of claim 4, wherein the planar region further includes a fourth side that is opposite to the third side, and a profile of the fourth side has mirror symmetry with the profile of the third side in the plan view.

8. The display device of claim 4, wherein the planar region further includes a fourth side that is opposite to the third side, and a profile of the fourth side is the same as the profile of the third side in the plan view.

9. The display device of claim 1, wherein the first pixel opening, the second pixel opening, the third pixel opening, and the sensor hole are spaced apart from each other in the plan view.

10. The display device of claim 1, wherein the pixel defining layer includes a light blocking material.

11. The display device of claim 1, further comprising:
an optical device disposed under the substrate to correspond to the sensor hole.

12. The display device of claim 1, further comprising:
a plurality of unit light emitting areas repeatedly arranged on the substrate,
wherein each of the plurality of unit light emitting areas includes a first light emitting area corresponding to the first pixel opening, a second light emitting area corresponding to the second pixel opening, and a third light emitting area corresponding to the third pixel opening, and
wherein light emitted from the first light emitting area has a first color, light emitted from the second light emitting area has a second color that is different from the first color, and light emitted from the third light emitting area has a third color that is different from the first color and the second color.

13. A display device, comprising:
a substrate;
first to third pixel electrodes disposed on the substrate; and
a pixel defining layer including a first pixel opening, a second pixel opening, a third pixel opening, and a sensor hole, the first pixel opening exposing a portion of the first pixel electrode, the second pixel opening exposing a portion of the second pixel electrode, the third pixel opening exposing a portion of the third pixel electrode, the sensor hole being disposed with one pixel opening of the first to third pixel openings on one side thereof and two remaining pixel openings of the first to third pixel openings on another side thereof,
wherein the first pixel opening includes a first sub-pixel opening exposing a first portion of the first pixel electrode and a second sub-pixel opening exposing a second portion of the first pixel electrode,
wherein a first planar region defined along sides of the first sub-pixel opening and sides of the second sub-pixel opening includes a first side adjacent to the sensor hole, and a profile of the first side curves around the sensor hole in a plan view, and
wherein the first planar region has a concave shape with respect to a direction away from the sensor hole along the profile of the first side in the plan view.

14. The display device of claim 13, wherein the first planar region further includes a second side that is opposite to the first side, and a profile of the second side is the same as the profile of the first side in the plan view.

15. The display device of claim 14, wherein the first planar region has a convex shape with respect to the direction away from the sensor hole along the profile of the second side in the plan view.

16. The display device of claim 13, wherein a second planar region defined along sides of the second pixel opening and sides of the third pixel opening has a third side adjacent to the sensor hole, and a profile of the third side curves around the sensor hole in the plan view, and
wherein the second planar region has a concave shape with respect to the direction away from the sensor hole along the profile of the third side in the plan view.

17. The display device of claim 16, wherein in the plan view, the first side of the first planar region and the third side of the second planar region face each other in a first direction with the sensor hole interposed therebetween.

18. The display device of claim 17, wherein the second pixel opening is disposed in the first direction from the first pixel opening,
wherein the third pixel opening is disposed in the first direction from the first pixel opening,
wherein the second pixel opening and the third pixel opening are disposed along a second direction that is perpendicular to the first direction, and
wherein the first sub-pixel opening and the second sub-pixel opening are disposed along the second direction.

19. The display device of claim 16, wherein the second planar region further includes a fourth side that is opposite to the third side, and a profile of the fourth side has mirror symmetry with or is the same as the profile of the third side in the plan view.

20. The display device of claim 13, wherein the first pixel opening, the second pixel opening, the third pixel opening, and the sensor hole are spaced apart from each other in the plan view.

21. The display device of claim 13, wherein the pixel defining layer includes a light blocking material.

22. The display device of claim 13, further comprising:
an optical device disposed under the substrate to correspond to the sensor hole.

23. The display device of claim 13, further comprising:
a plurality of unit light emitting areas repeatedly arranged on the substrate,
wherein each of the plurality of unit light emitting areas includes a first light emitting area corresponding to the first pixel opening, a second light emitting area corresponding to the second pixel opening, and a third light emitting area corresponding to the third pixel opening, and
wherein light emitted from the first light emitting area has a first color, light emitted from the second light emitting area has a second color that is different from the first color, and light emitted from the third light emitting area has a third color that is different from the first color and the second color.

24. An electronic device, comprising:
a display device; and
a power supply configured to provide power to the display device,
wherein the display device comprises:
a substrate;
first to third pixel electrodes disposed on the substrate; and
a pixel defining layer including a first pixel opening, a second pixel opening, a third pixel opening, and a sensor hole, the first pixel opening exposing a portion of the first pixel electrode, the second pixel opening exposing a portion of the second pixel electrode, the third pixel opening exposing a portion of the third pixel electrode, and the sensor hole being disposed with one pixel opening of the first to third pixel openings on one side thereof and two remaining pixel openings of the first to third pixel openings on another side thereof,
wherein the first pixel opening includes a first side adjacent to the sensor hole, and a profile of the first side curves around the sensor hole in a plan view, and
wherein the first pixel opening has a concave shape with respect to a direction away from the sensor hole, along the profile of the first side in the plan view.
